(19) United States
(12) Patent Application Publication
(10) Pub. No.: US 2025/0157891 A1
(43) Pub. Date: May 15, 2025

(54) BURIED METAL LINER IN SOURCE/DRAIN EPITAXIAL MATERIAL

(71) Applicant: International Business Machines Corporation, Armonk, NY (US)

(72) Inventors: Tsung-Sheng Kang, Ballston Lake, NY (US); Tao Li, Slingerlands, NY (US); Alexander Reznicek, Troy, NY (US); Ruilong Xie, Niskayuna, NY (US)

(21) Appl. No.: 18/509,672

(22) Filed: Nov. 15, 2023

(51) Int. Cl. H01L 23/485; H01L 29/417; H01L 29/66; H01L 29/78

(52) U.S. Cl. CPC H01L 23/485; H10D 30/025; H10D 30/63; H10D 64/252

(57) ABSTRACT

Embodiments of the present disclosure include a semiconductor structure including a transistor. The transistor includes a channel region separating a first epitaxial region from a second epitaxial region. A conductive piece is embedded in the first epitaxial region.

### BACKGROUND

The present disclosure generally relates to fabrication methods and resulting structures for integrated circuits (ICs), and more specifically, to fabrication methods and resulting structures having a buried metal liner inside source/drain epitaxial material for vertical transport field effect transistors.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products of the future is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

Another nonplanar MOSFET that uses fin-shaped structures is a vertical FET. A vertical FET operates like a normal FinFET that is horizontal. However, in a vertical FET (VFET) also referred to as a vertical transport field effect transistor (VTFET), the entire fin functions as the channel, and the source and drain regions are positioned at respective ends of the vertically positioned fin such that the current runs vertically from source to drain. Also, the gate of a VTFET usually wraps around the fin-shaped channel.

### SUMMARY

Embodiments of the present disclosure are directed to transistors having a buried metal liner inside source/drain epitaxial material for vertical transport field effect transistors. A non-limiting method of forming a semiconductor structure includes providing a transistor including a channel region separating a first epitaxial region from a second epitaxial region and embedding a conductive piece in the first epitaxial region.

According to one or more embodiments, a non-limiting method of forming a semiconductor structure includes providing a transistor including a channel region separating a first epitaxial region from a second epitaxial region and embedding a conductive piece in the first epitaxial region. A contact is coupled to the first epitaxial region, the conductive piece being electrically coupled to both the channel region and the contact.

Other embodiments of the present disclosure implement features of the above-described devices/structures in methods and/or implement features of the methods in devices/structures.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIGS. 1A and 1B respectively depict a top view and cross-sectional view of a portion of an integrated circuit (IC) under-fabrication according to one or more embodiments;

FIGS. 2A, 2B, and 2C, respectively depict a top view and cross-sectional views of a portion of an IC under-fabrication after fabrication operations according to one or more embodiments;

FIGS. 3A, 3B, and 3C respectively depict a top view and cross-sectional views of a portion of an IC under-fabrication after fabrication operations according to one or more embodiments;

FIGS. 4A, 4B, and 4C respectively depict a top view and cross-sectional views of a portion of an IC under-fabrication after fabrication operations according to one or more embodiments;

FIGS. 5A, 5B, and 5C respectively depict a top view and cross-sectional views of a portion of an IC under-fabrication after fabrication operations according to one or more embodiments;

FIGS. 6A, 6B, and 6C respectively depict a top view and cross-sectional views of a portion of an IC under-fabrication after fabrication operations according to one or more embodiments;

FIGS. 7A, 7B, 7C, and 7D respectively depict a top view and cross-sectional views of a portion of an IC under-fabrication after fabrication operations according to one or more embodiments;

FIGS. 8A, 8B, 8C, and 8D respectively depict a top view and cross-sectional views of a portion of an IC under-fabrication after fabrication operations according to one or more embodiments;

FIGS. 9A, 9B, 9C, 9D, and 9E respectively depict a top view and cross-sectional views of a portion of an IC under-fabrication after fabrication operations according to one or more embodiments;

FIGS. 10A, 10B, 10C, 10D, and 10E respectively depict a top view and cross-sectional views of a portion of an IC under-fabrication after fabrication operations according to one or more embodiments;

FIGS. 11A, 11B, 11C, 11D, and 11E respectively depict a top view and cross-sectional views of a portion of an IC under-fabrication after fabrication operations according to one or more embodiments;

FIGS. 12A, 12B, 12C, 12D, and 12E respectively depict a top view and cross-sectional views of a portion of an IC under-fabrication after fabrication operations according to one or more embodiments;

FIGS. 13A, 13B, 13C, and 13D respectively depict a top view and cross-sectional views of a portion of an IC under-fabrication after fabrication operations according to one or more embodiments;

FIG. 14 depicts a flowchart of a method of forming a semiconductor structure according to one or more embodiments; and

FIG. 15 depicts a flowchart of a method of forming a semiconductor structure according to one or more embodiments.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

One or more embodiments provide a slim metal rail or metal rails embedded into an elongated semiconductor source or drain region for vertical transport field effect transistors (VTFET). In one or more embodiments, an FET includes a pair of semiconductor source/drain regions where one source/drain region is asymmetrically elongated and slim metallic rails are embedded into the elongated source/drain region. In one or more embodiments, the aspect ratio (width to height) of the slim metallic rails is larger than two. According to one or more embodiments, the metallic rails include metallic compounds selected from a group including metal silicides, germanosilicides, and metal nitrides. In one or more embodiments, the source/drain semiconductor doping may be in excess of 5×10²⁰/cm³. According to one or more embodiments, the specific contact resistivity between the metal rails and adjacent semiconductor material is around 5×10⁻⁹ Ohm·cm².

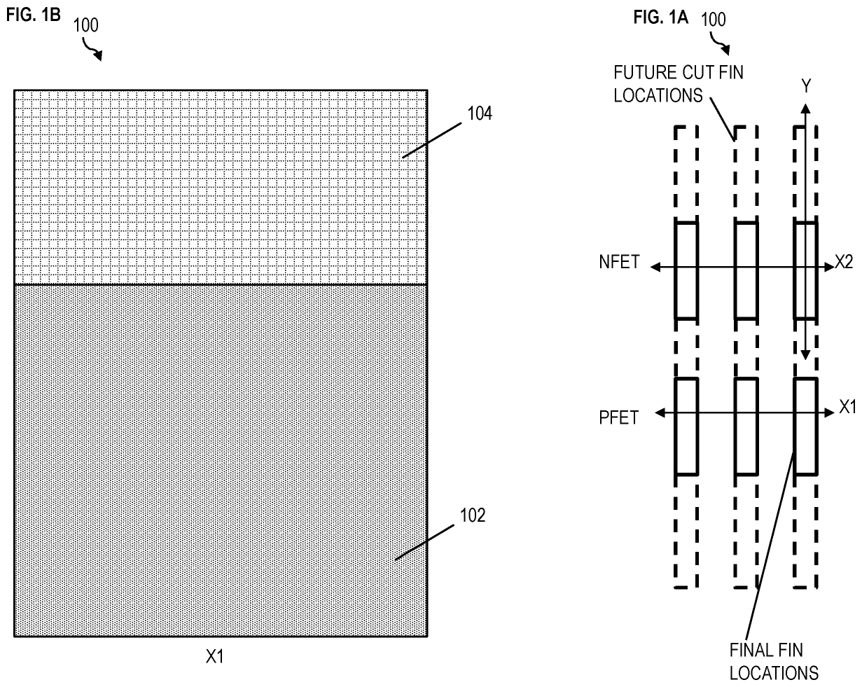

Turning now to a more detailed description of aspects of the present disclosure, FIG. 1A depicts a top view of a simplified illustration of a portion of an integrated circuit (IC) 100 and FIG. 1B depicts a cross-sectional view taken along X1 of the IC 100. Additional cross-sectional views may be depicted along X2, X3, and Y in subsequent figures. For ease of understanding, some layers may be omitted from the various top views so as not to obscure the figure and to view layers underneath. As such, the top view is intended to provide a simplified illustration and a general orientation of a portion of the IC. Some future locations of features may be illustrated in the top view. Standard semiconductor fabrication techniques can be utilized to fabricate the IC as understood by one of ordinary skill in the art. Any suitable lithography processes including deposition techniques and etching techniques can be utilized herein.

FIGS. 1A and 1B depict the IC 100 having a wafer as a substrate 102, and a hardmask layer 104 is formed on the substrate 102. The wafer or substrate 102 may be formed of (pure) silicon. Other suitable materials can be utilized for the substrate 102.

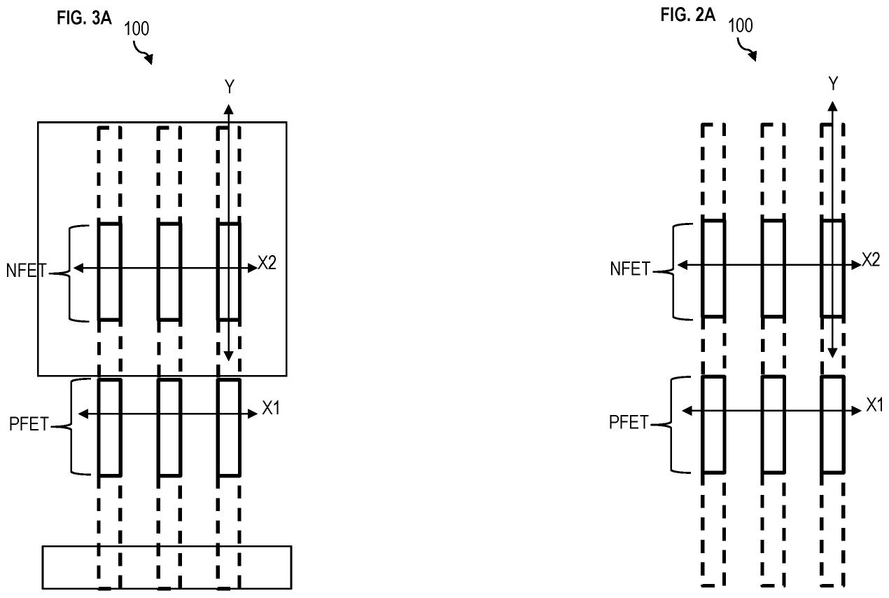

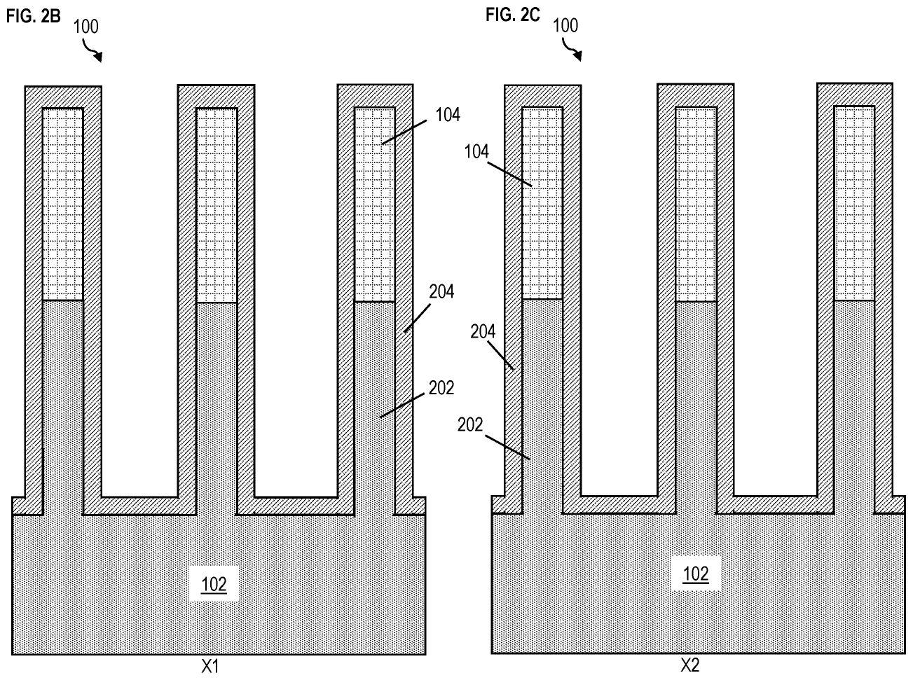

FIGS. 2A, 2B, and 2C depict the IC 100 after fin etching. FIG. 2C depicts a cross-sectional view taken along X2 of the IC 100. Lithography is utilized to pattern the hardmask layer 104, for example, using a patterned photoresist material. The patterned hardmask layer 104 can be used as a mask to form fins 202 in part of the substrate 102 using, for example, a reactive ion etch (RIE). The hardmask layer 104 can be a single layer or hardmask stack. Example materials for the hardmask layer 104 can include one or more layers of amorphous carbon, organo siloxane based materials, silicon nitride (SiN), silicon oxynitride (SiON), titanium nitride (TiN), etc. Example materials of the substrate 102 as well as the fins 202 can include silicon (Si), silicon germanium (SiGe), III-V semiconductors, etc. Dopants can be added to the fins 202 as desired to enhance carrier properties. The fins 202 can be described as vertical fins in which the entire fin functions as the vertical channel, which is the channel region, and the source and drain regions are positioned at respective ends of the vertically positioned fin such that the electrical current runs vertically from source to drain, thus forming a VTFET.

A sacrificial layer 204 is deposited on the fins 202, hardmask layer 104, and substrate 102. The sacrificial layer 204 can include one or more layers of material. Example materials of the sacrificial layer 204 can include a stack having a first liner such as nitride materials (e.g., silicon nitride (SiN)), an oxide material (e.g., SiO₂) formed on the first liner, and a second liner (e.g., silicon nitride (SiN)) formed on the oxide material.

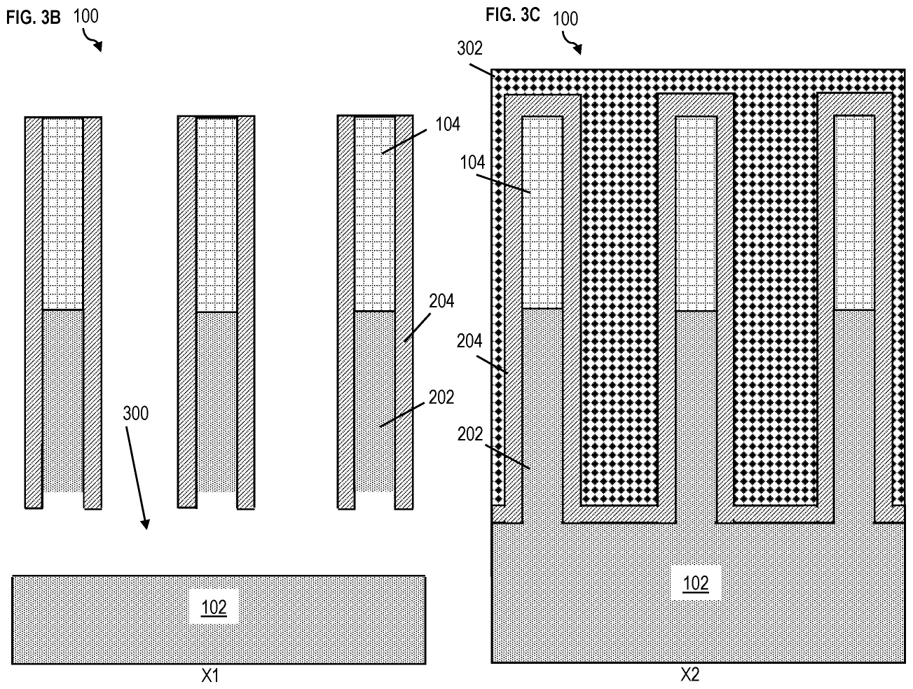

FIGS. 3A, 3B, and 3C depict the IC 100 after opening a source/drain cavity in preparation for deposition of source/drain epitaxial material. A block mask 302 is formed on the NFET side and is open at the PFET side. The block mask 302 protects the NFET side from subsequent processing related to the PFET side, while an analogous process it to occur when processing the NFET side. The block mask 302 can be a lithography stack. The block mask 302 can include an organic planarization layer (OPL). The block mask 302 can include a hardmask or any protective polymer material.

Etching is performed which results in breakthrough at the tops of the fin hardmask layer 104 and between the fins 202 on the PFET side while the NFET side is protected. For example, etching is performed to remove the sacrificial layer 204 from the tops of the hardmask layer 104, along with removing portions of the sacrificial layer 204 from in between the fins 202 and on the surface of the substrate 102. A RIE etch can be used. After the RIE etch, the hardmask layer 104 is exposed above the fins 202, and the portions of the substrate 102 are exposed in preparation of an isotropic etch.

Because of the exposed substrate 102, isotropic etching is performed to remove portions of the substrate 102 underneath the fins 202 in order to create opening 300 (or gap), and this etching can remove the footing of the fins 202. A dry etch can be utilized and/or a wet etch can be utilized, and the etch is intended to etch laterally and vertically. Further, during the etching to create the opening 300, other regions of the fins 202 are protected by the block mask 302 and these other regions are used as anchors to support the opening 300, thereby preventing the fin portions having openings 300 from falling/flopping over or collapsing. It should be appreciated that the fins 202 extend lengthwise beyond distance of the etching.

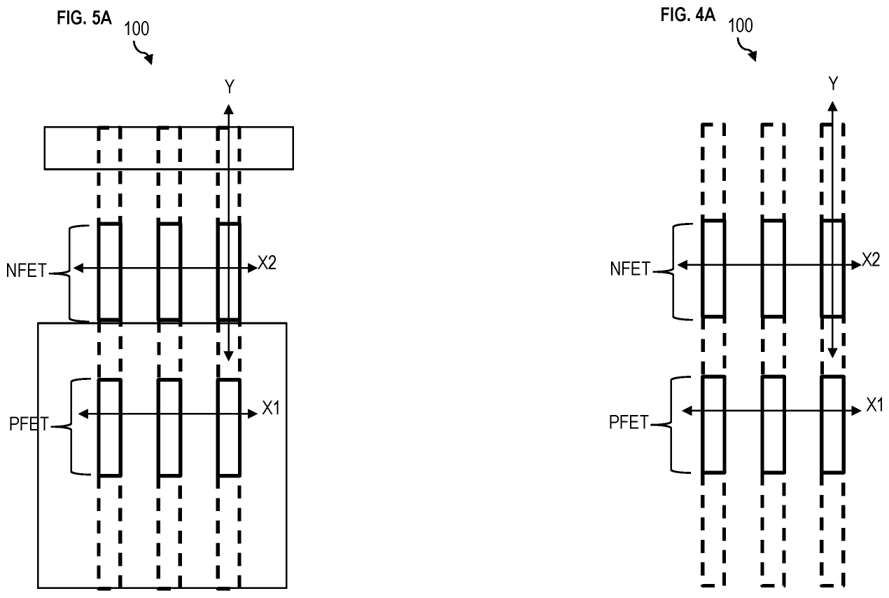

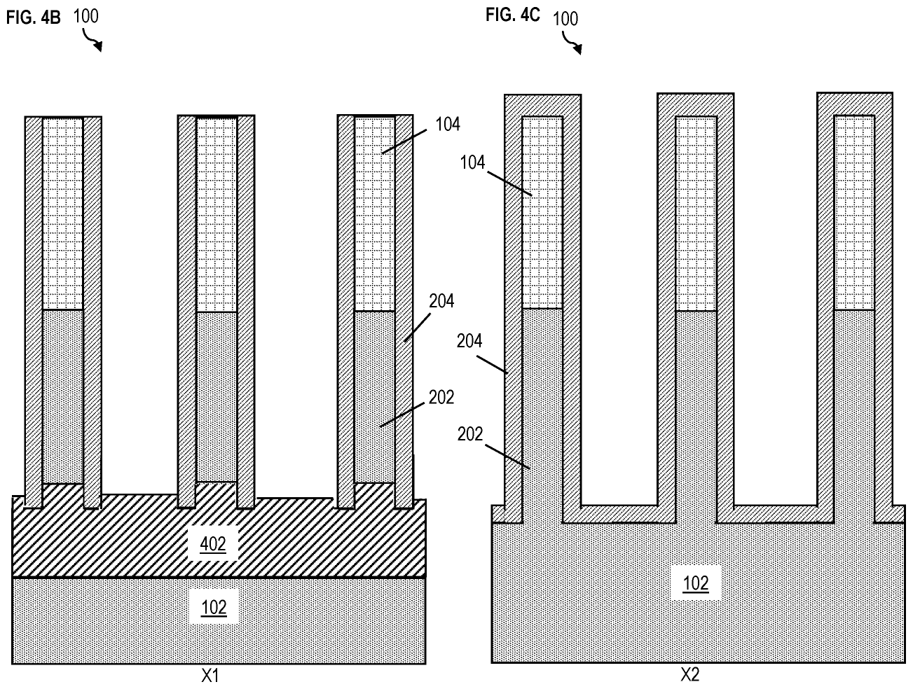

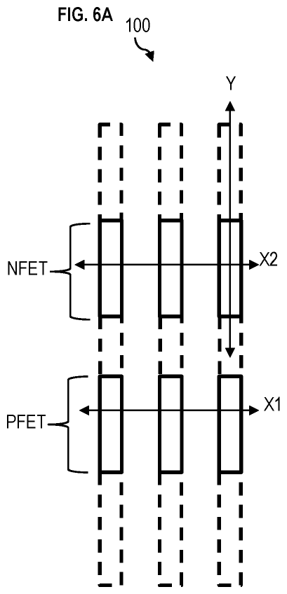

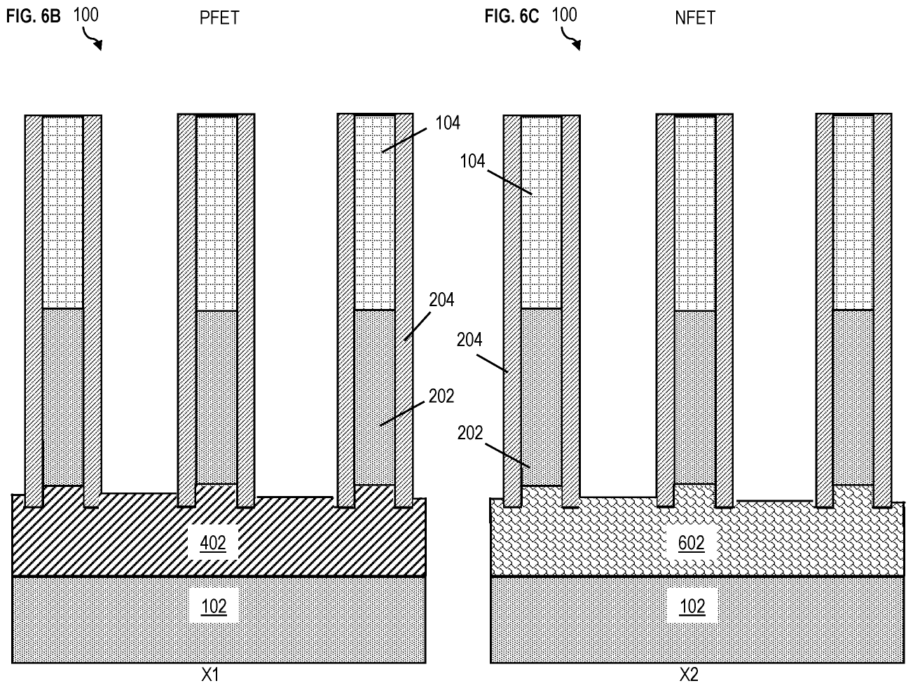

FIGS. 4A, 4B, and 4C depict the IC 100 after deposition of p-type epitaxial material. A bottom epitaxial material is deposited to form bottom source/drain region 402. The material of the bottom source/drain region 402 is in accordance with the type of transistor being formed. The epitaxial material of the bottom source/drain region 402 epitaxially grows from both the fin bottom of the fins 202 and the substrate 102. Because FIG. 4B illustrates a PFET device, the bottom source/drain region 402 is a semiconductor material doped with p-type dopants. When forming the NFET device, the bottom source/drain layer are doped with n-type dopants (as depicted in FIG. 6C). Although not shown, it should be appreciated that the block mask 302 can be removed from the NFET side after opening the sacrificial layer 204 on the PFET side, and an OPL ash can be performed to remove the block mask 302 that protected NFET side in FIG. 3C. The subsequent epitaxial growth of bottom source/drain region 402 does not occur on the NFET side, because the sacrificial layer 204 still covers the substrate 102 and fins 202.

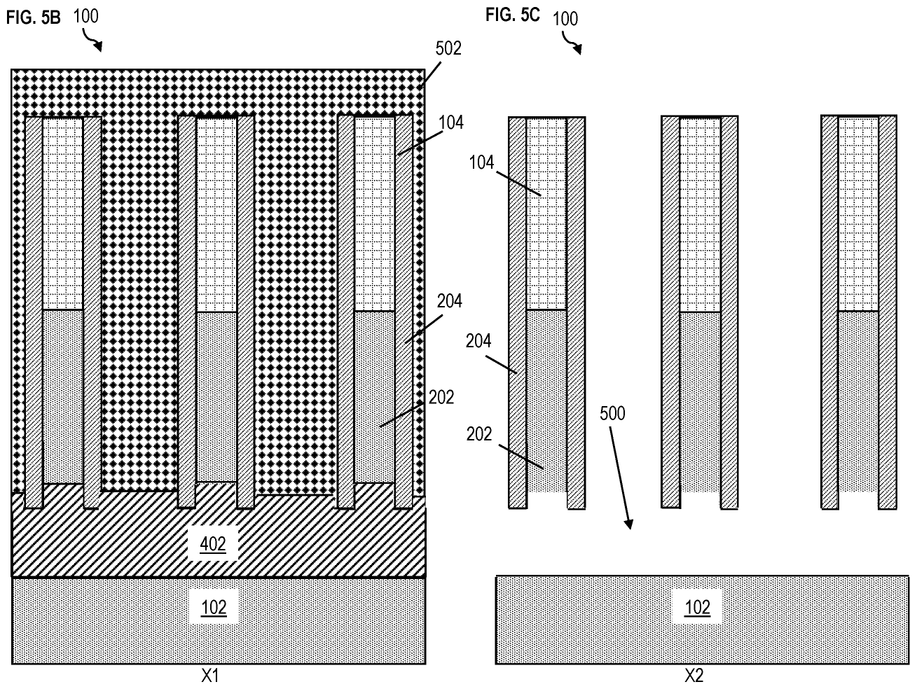

FIGS. 5A, 5B, and 5C depict the IC 100 after opening a source/drain cavity in preparation for deposition source/drain epitaxial material. Analogous to the fabrication processes discussed for the PFET side, these processes are repeated but switched for the NFET side. For example, the PFET side having the bottom source/drain region 402 formed is protected by a block mask 502. Analogously, the NFET side is etched to remove portions of the sacrificial layer 204 above the hardmask layer 104 and between the fins 202, and etching continues on the NFET side to create an opening 500. Once the NFET side is etched, the block mask over the PFET side is removed in the next fabrication operation.

FIGS. 6A, 6B, and 6C depict the IC 100 after deposition of n-type epitaxial material. A bottom epitaxial material is deposited to form bottom source/drain region 602. The material of the bottom source/drain region 602 is in accordance with the type of transistor being formed. The material of the bottom source/drain region 602 is for an NFET device, and as such, the bottom source/drain region 602 can be doped with n-type dopants.

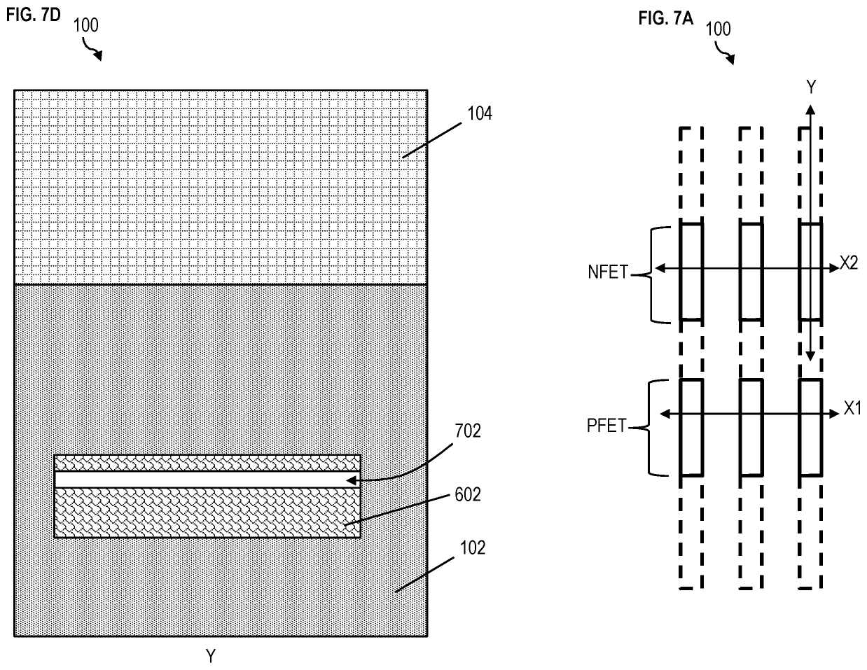

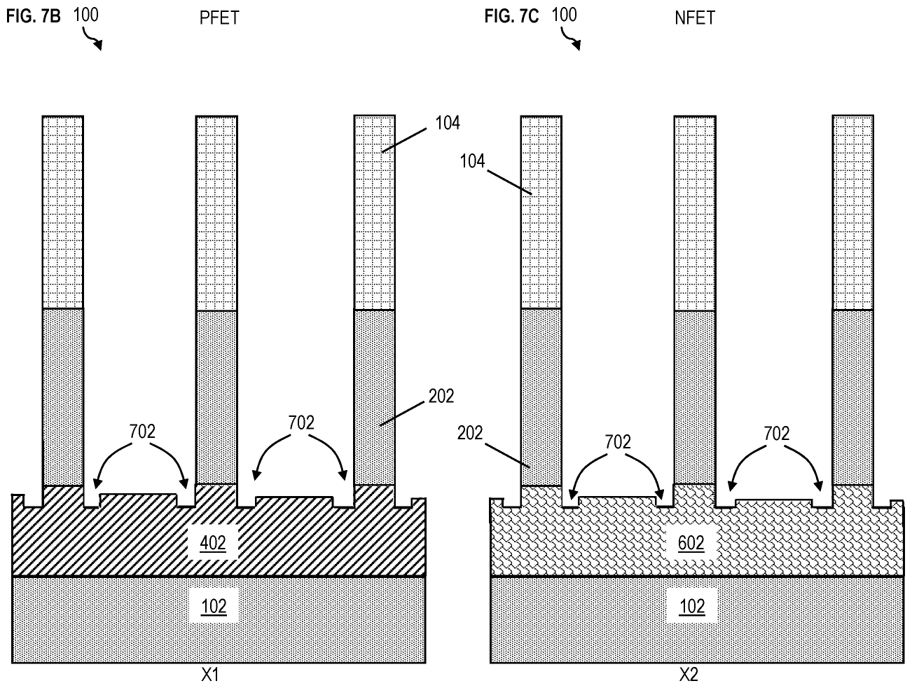

FIGS. 7A, 7B, 7C, and 7D depict the IC 100 after removal of the sacrificial layer 204. FIG. 7D depicts a cross-sectional view of the IC 100 taken along Y. The sacrificial layer 204 is etched away leaving trenches 702, which includes removal of the first liner (e.g., SiN), the oxide material (e.g., SiO₂) on top of the first liner, and the second liner (e.g., SiN) on top of the oxide material. A wet etch or dry etch can be used.

In one or more embodiments, it is noted that all trench surfaces of the epitaxial material were treated/doped to at least a 5×10²⁰/cm³ active doping concentration by known surface doping and techniques such as, for example, surface implantation plus anneal, gas phase doping, etc. One or more embodiments can have a portion of an ultra-thin doped epitaxial growth of 2-4 nanometers (nm), although other thicknesses possible.

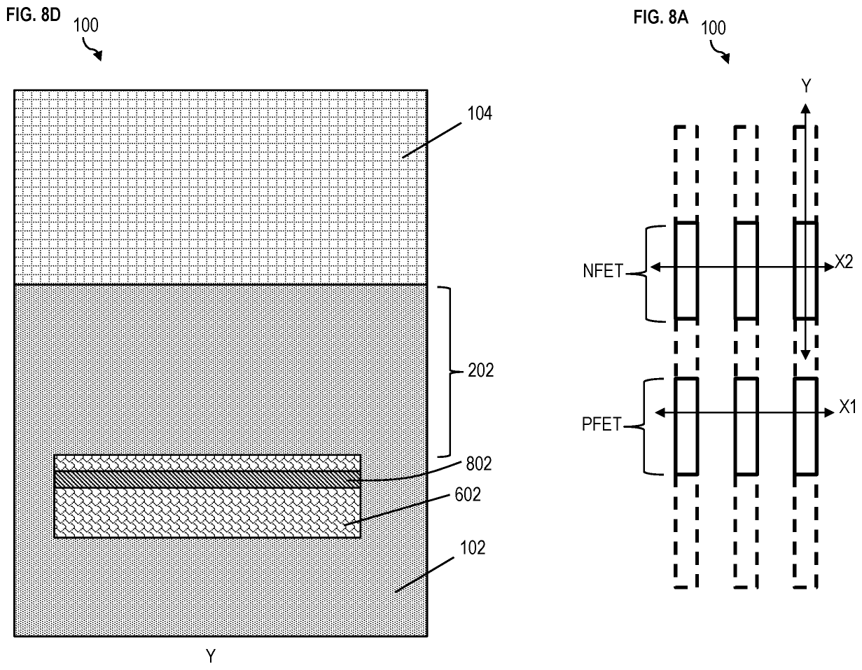

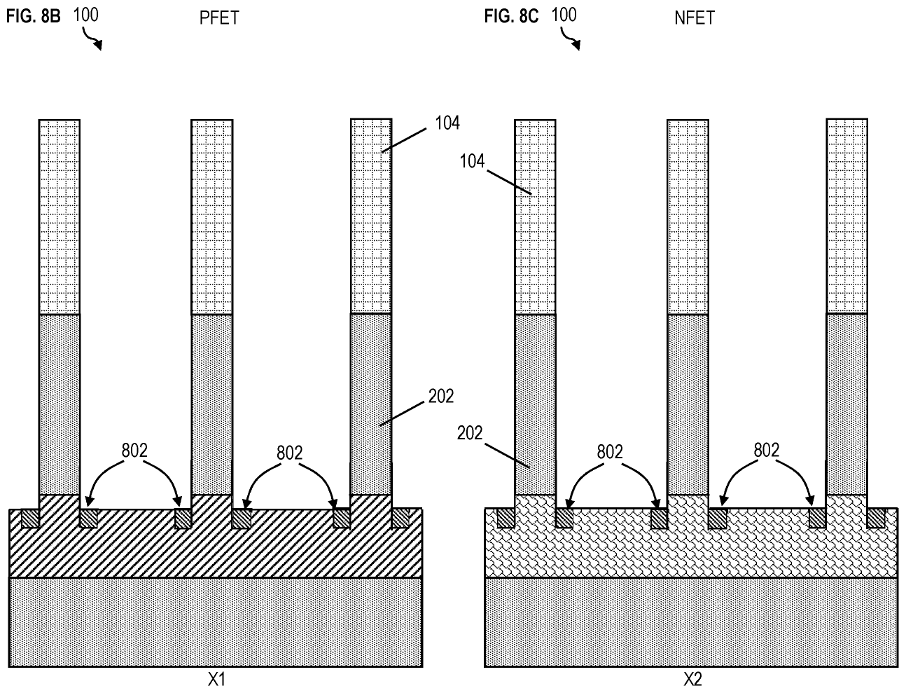

FIGS. 8A, 8B, 8C, and 8D depict the IC 100 after metal fill in the trenches. Atomic layer deposition (ALD) of metal is performed to fill the trenches 702 and isotropic etch back is performed, resulting in conductive pieces that are labeled as metal liners 802. Thermal annealing is performed. The conductive pieces in the epitaxial material can be referred to as metal liners 802, metal rails, metal inner spacers, etc.

The deposited metal of the metal liners 802 can include ruthenium (Ru), tungsten (W), titanium (Ti), molybdenum (Mo), etc. In one or more embodiments, the metal type used can be a bilayer of, for example, Ti/TiN, which converts into the bilayer TiSi/TiN after thermal annealing; this results in thermally stable silicide with good resistivity for both NFETs with n-type epitaxial material and PFETs with p-type epitaxial material.

In one or more embodiments, the final structure (after thermal anneal) of the metal liners 802 may not have a pure elemental metal but rather a metal designated as “Me” in a metallic compound. The representative metal “Me” can include Ru, W, Ti, Mo, etc. The material of the metal liners 802 can include metallic compounds such as MeSi, MeGeSi, etc., and can include bilayers of the metallic compounds such as MeSi/Me, MeGeSi/Me, etc. In one case, the metal “Me” and silicon can be deposited in the trench, thus forming the metallic compound MeSi after thermal annealing. In another case, the metal “Me” and germanium silicon can be deposited in the trench, thus forming the metallic compound MeGeSi after thermal annealing.

The combination of high interfacial surface doping and interfacial silicide brings the specific contact resistance to around 5×10⁻⁹ Ohm·cm² and enables the electrical benefit.

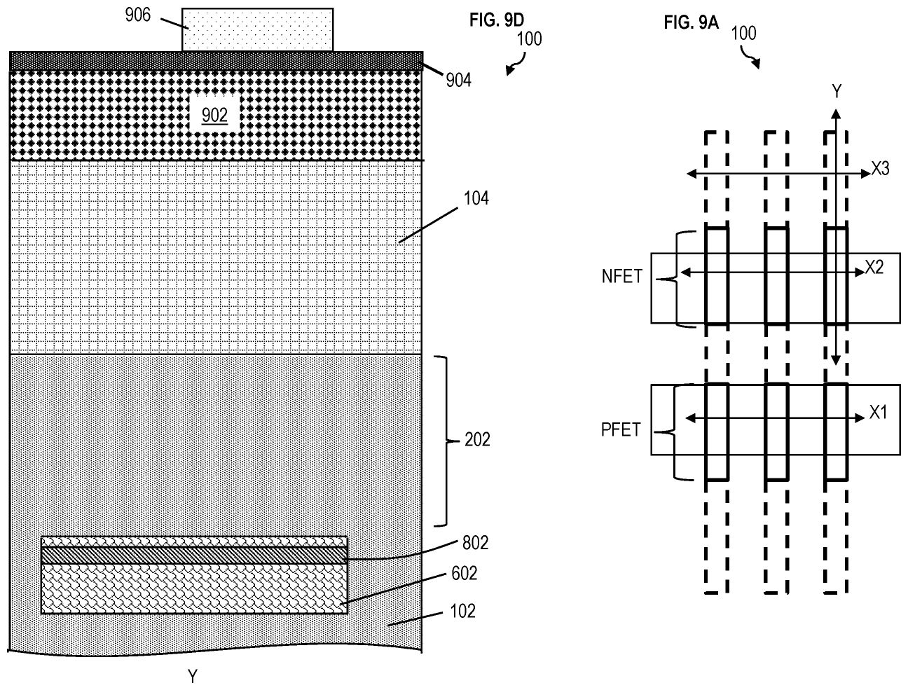

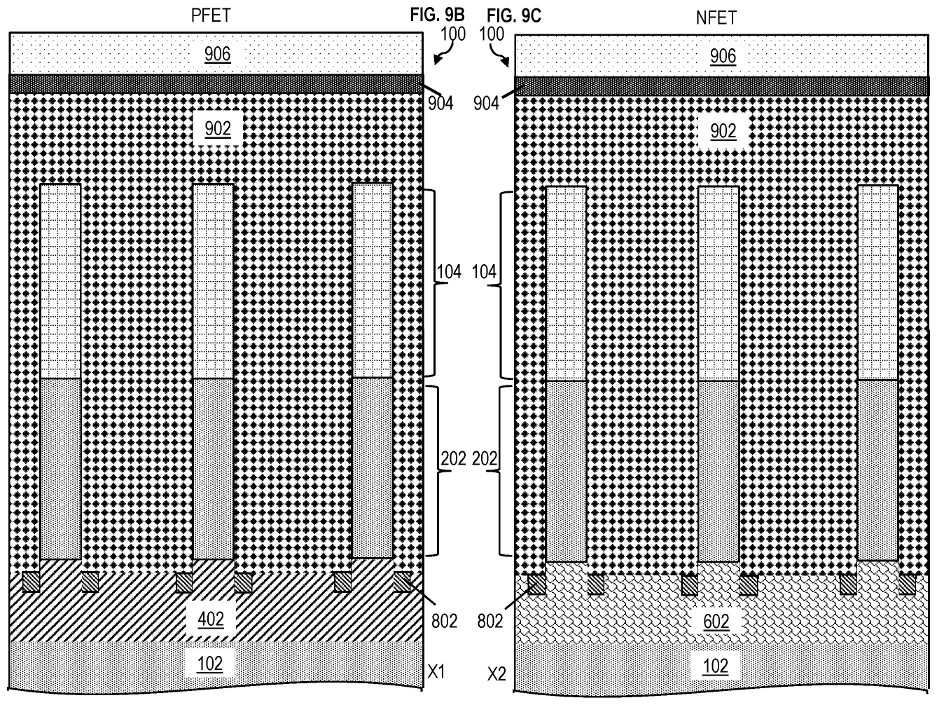

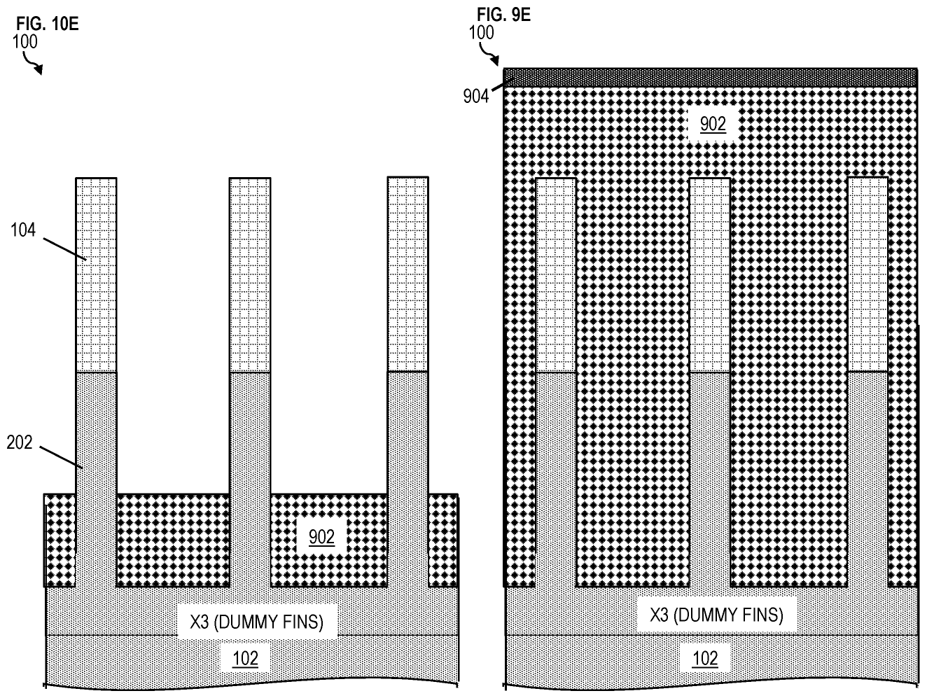

FIGS. 9A, 9B, 9C, 9D, and 9E depict the IC 100 after fin cut last patterning. FIG. 9E depicts a cross-sectional view of the IC 100 taken along X3 for dummy fins. A block mask 902, a hardmask layer 904, and photoresist material 906 are deposited. The photoresist material 906 is developed and patterned in preparation for etching.

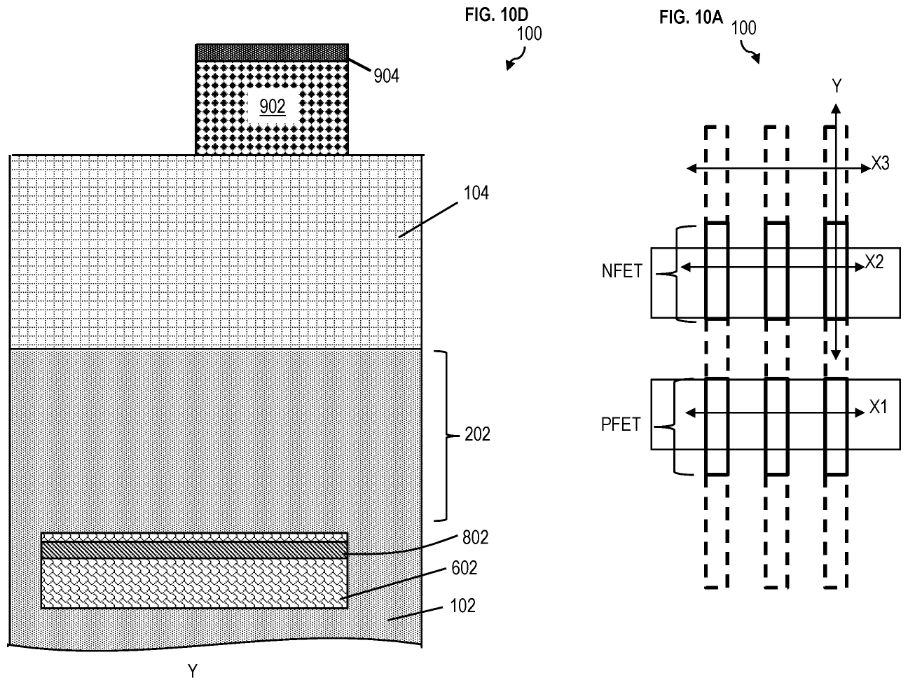

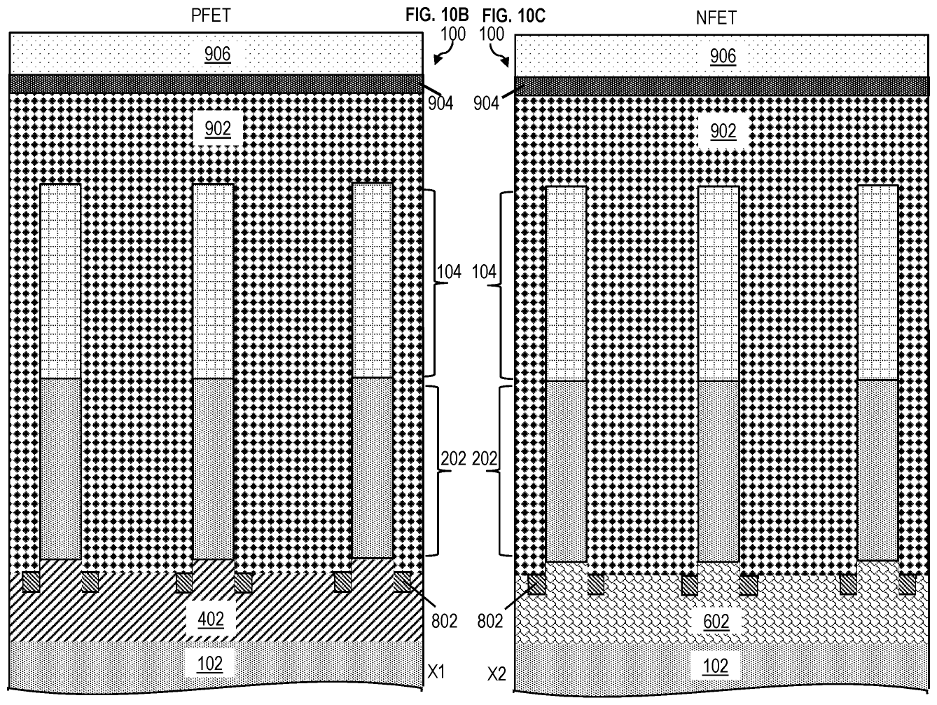

FIGS. 10A, 10B, 10C, 10D, and 10E depict the IC 100 after etching the block mask. A partial etch of the block mask 902 is performed in accordance with the pattern of the photoresist material 906 as depicted in FIG. 10D. The hardmask layer 104 is protected by the photoresist material 906 on the PFET side and NFET side during the partial etch of block mask 902 as depicted in FIGS. 10B and 10C.

A hardmask open and block mask partial open occur from etching, and FIG. 10E illustrates that the etching exposes (dummy) fins 202 and hardmask layer 104. In FIG. 10E, the etching ensures that part of the block mask 902 is still on the surface of the substrate 102 between the fins 202 at the dummy fin region, which is in preparation for the fin cut of only the dummy fins.

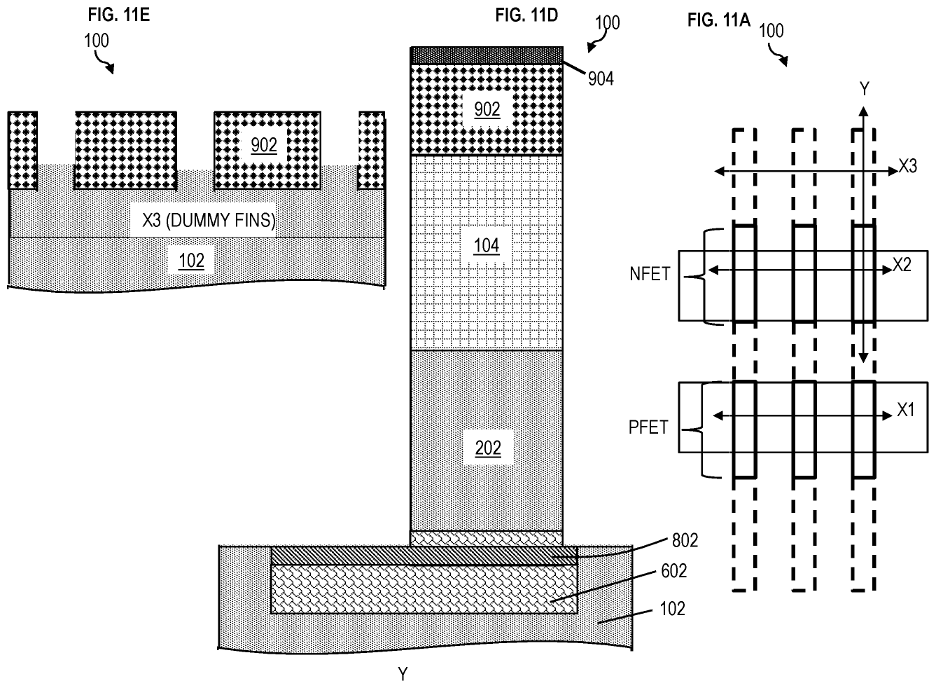

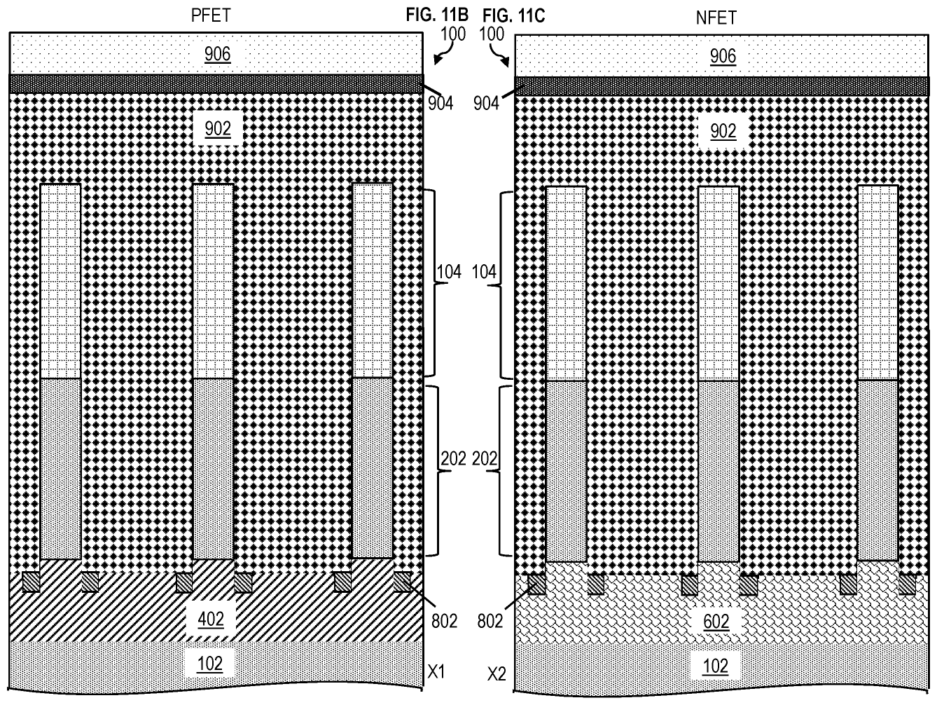

FIGS. 11A, 11B, 11C, 11D, and 11E depict the IC 100 after fin cut. Etching is performed and the areas protected by the hardmask layer 904 are protected. For example, the photoresist material 906 is removed. During the fin cut, the hardmask layer 904 and block mask 502 protect the PFET side and NFET side in FIGS. 11B and 11C. After performing the fin cut, FIG. 11D shows that the part of the hardmask layer 104, part of the (dummy) fins 202, and part of the bottom source/drain region 602 have been removed, thereby exposing a top surface of part of the metal liner 802. As a result of the fin cut, the hardmask layer 104 and the (dummy) fins 202 are etched away in FIG. 11E.

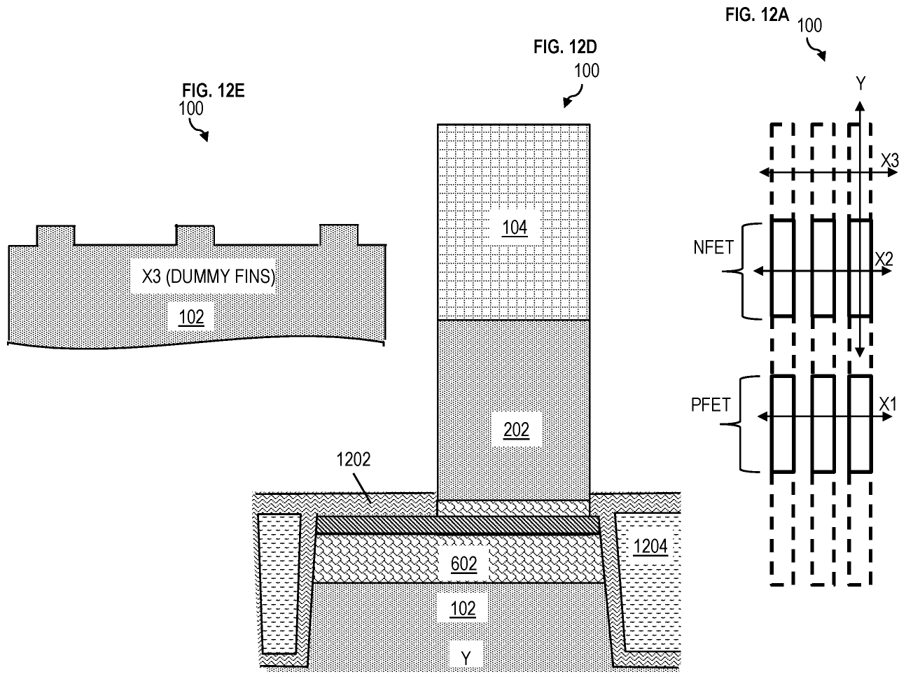

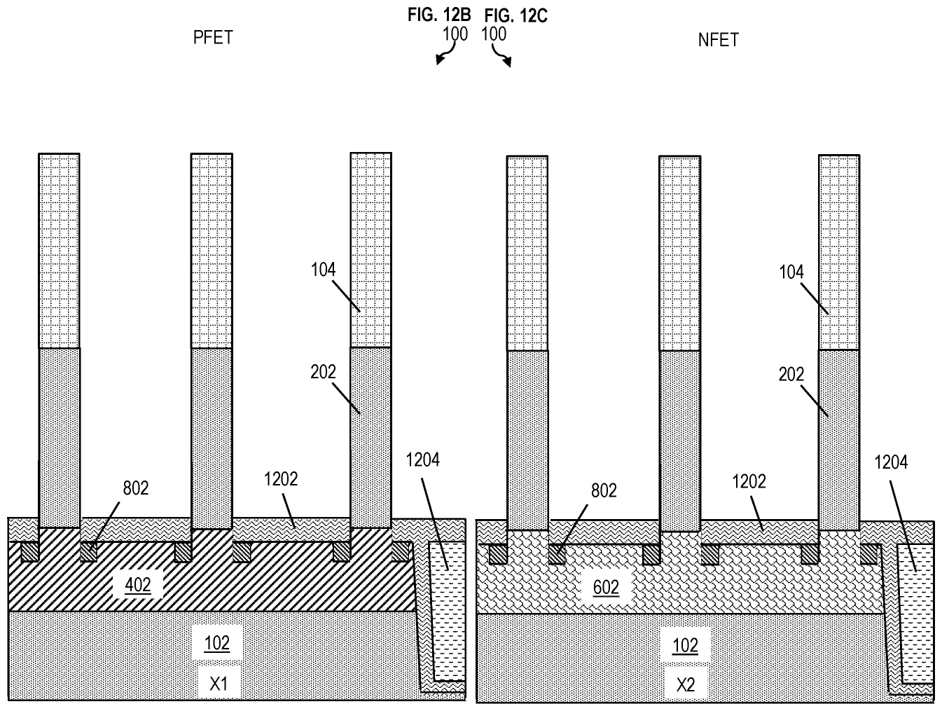

FIGS. 12A, 12B, 12C, 12D, and 12E depict the IC 100 after several fabrication processes including active region patterning, shallow trench isolation (STI) formation, and bottom spacer formation. The block mask 902, hardmask layer 904, and photoresist material 906 are removed. Active transistor regions are defined by creating STI regions. For example, trenches for STI regions are formed, and spacer material 1202 can be formed to line the STI trenches. The spacer material 1202 can be a stack including an oxide liner (e.g., SiO₂) formed on walls of the STI trenches and a nitride material (e.g., SiN) formed on top of the oxide liner. Further examples of the spacer material 1202 can include porous SiCN, SiCOH, and octamethylcyclotetrasiloxane (OMCTS). STI material 1204 is formed in the STI trenches. The STI material 1204 can be a dielectric material, a low-k dielectric material or an ultra-low-k dielectric material. The STI material 1204 can be an oxide, such as, for example silicon dioxide. The dielectric constant (k) of the low-k dielectric material can be equal to or less than about 3.0 in one or more embodiments. Further, the dielectric constant (k) of the low-k dielectric material can be equal to or less than about 3.7 or 3.9 in one or more embodiments.

Additional spacer material 1202 is deposited to cover the STI material 1204. The spacer material 1202 also covers the metal liners 802, thereby burying any portions of the metal liners 802 that were previously exposed.

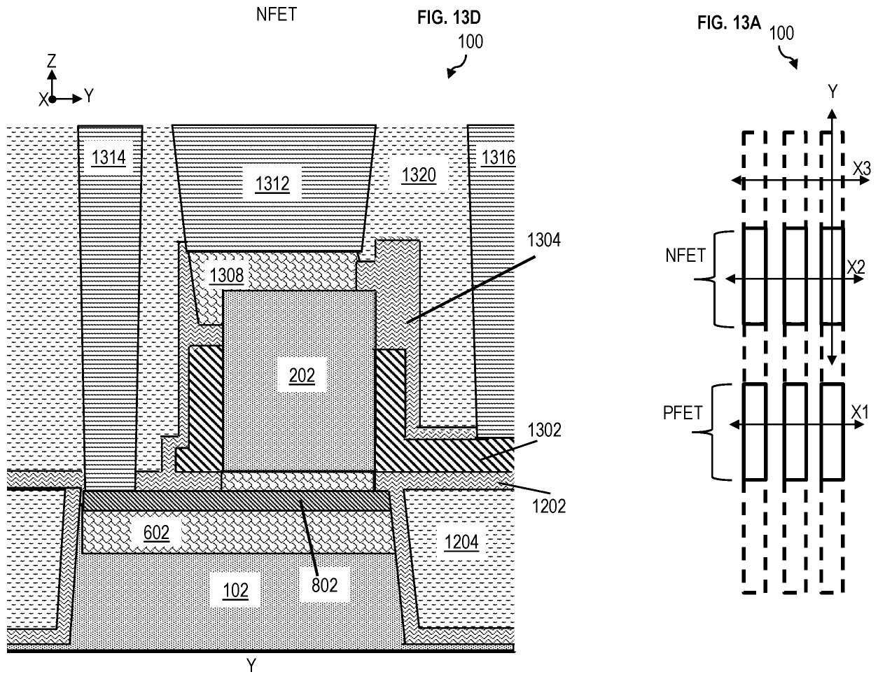

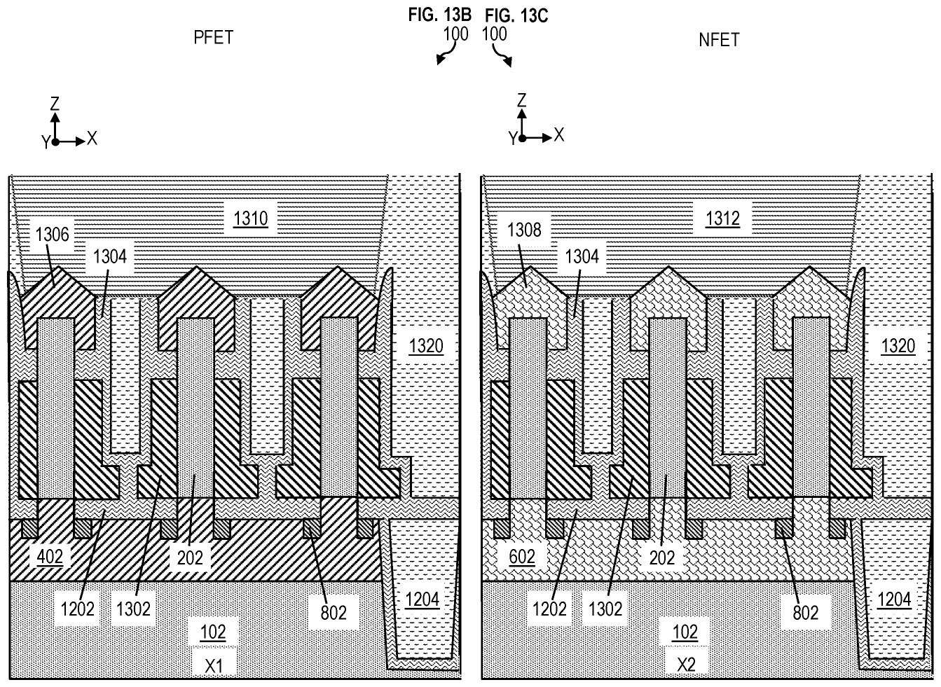

FIGS. 13A, 13B, 13C, 13D, and 13E depict the IC 100 after performing the process of record (POR). Gate material 1302 is formed to surround the fin 202. The gate material 1302 can include a gate stack formed of a high-k dielectric material formed on the fins 202 and a workfunction material formed on the high-k dielectric material. In one or more embodiments, the high-k dielectric material can have a dielectric constant greater than the dielectric constant of silicon dioxide (i.e., greater than 3.7-3.9). Examples of high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). The workfunction material includes a work function suitable for enhancing the electrical properties of n-type or p-type semiconductor devices depending on the type of transistor being formed.

A top spacer layer 1304 is formed on top of the gate material 1302. The top spacer layer 1304 can be dielectric material, a low-k dielectric material, or ultra-low-k dielectric material and can include materials used for the bottom spacer layer formed by the spacer material 1202. Top source/drain regions 1306 and 1308 are formed on top of the fins 202. The top source/drain regions 1306 and 1308 can be epitaxial material grown from the fins 202. The top source/drain regions 1306 and 1308 can be a semiconductor material appropriately doped with p-type dopants or n-type dopants depending on the type of transistor being formed. Inter-layer dielectric or inter-level dielectric (ILD) material 1320 is deposited and chemical mechanical polishing/planarization (CMP) is performed. The ILD material 1320 can include dielectric materials having a dielectric constant (k) equal to or less than about 2.5 or equal to or less than about 2.0 in one or more embodiments. Trenches for the top source/drain contacts, bottom source/drain contacts, and gate contacts can be formed in preparation for metallization. Metallization is performed to form top source/drain contact 1310 on top of the top source/drain regions 1306 and form top source/drain contact 1312 on top of the top source/drain regions 1308. Also, bottom source/drain contact 1314 is formed on top of the bottom source/drain region 602 (as well as the bottom source/drain region 402 for the PFET side), and gate contact 1316 is formed on the gate material 1302. Example materials used for metallization can include copper, aluminum, tungsten, tungsten cobalt, ruthenium, nickel, etc.

In one or more embodiments, an intervening layer (not shown) with a higher doping concentration may be formed between the top source/drain contact and the top source/drain region, the bottom source/drain contact and the bottom/source drain region, and the gate contact and the gate material. In one or more embodiments, an intervening layer is not formed between the bottom source/drain contact 1314 and the metal liner 802.

As technical solutions and benefits, the (buried) metal liners 802 reduce the bottom source/drain lateral resistance between the bottom source/drain contact 1314 and the fin 202. Particularly, the (buried) metal liners 802 have a lower resistance for carrying electrical current (in the y-axis) between the channel region (i.e., the fins 202) and the bottom source/drain contact 1314 as compared to the higher resistance in the bottom source/drain epitaxial material.

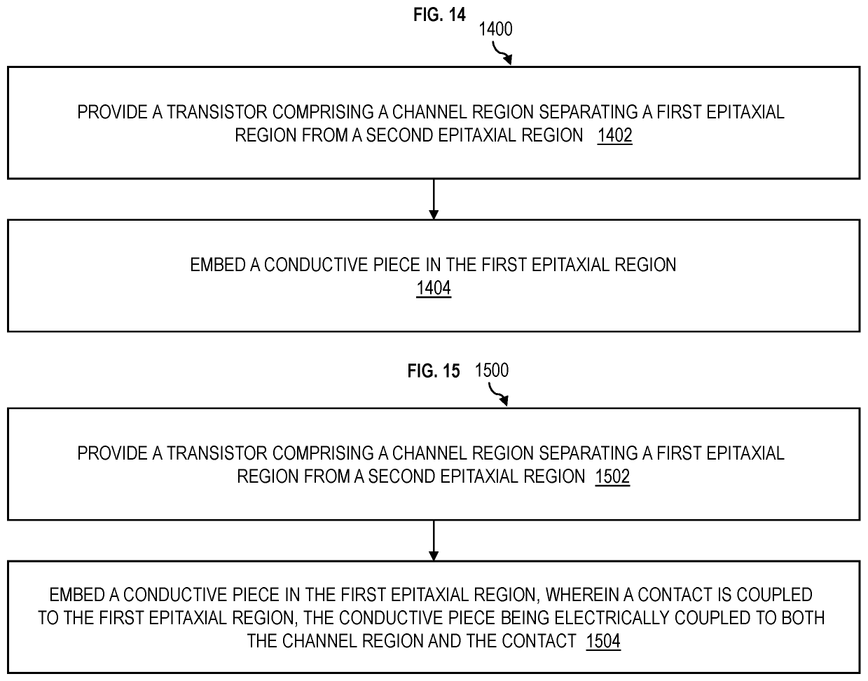

FIG. 14 depicts a flowchart of a method 1400 of forming a buried metal liner inside source/drain epitaxial material for vertical transport field effect transistors according to one or more embodiments. Reference can be made to any figures discussed herein. At block 1402, the method 1400 includes providing a transistor (e.g., PFET and/or NFET) including a channel region (e.g., fins 202) separating a first epitaxial region (e.g., bottom source/drain regions 402 and 602) from a second epitaxial region (e.g., top source/drain regions 1306 and 1308). At block 1404, the method 1400 includes embedding at least one conductive piece (e.g., metal liner 802) in the first epitaxial region (e.g., top source/drain regions 1306 and 1308).

Further, the conductive piece (e.g., metal liner 802) comprises a metal. Example metals may include Ru, W, Ti, Mo, etc. The conductive piece is metallic. The conductive piece extends from the channel region to a contact (e.g., metal liner 802 extends from the fin 202 to the bottom source/drain contact 1314). The conductive piece (e.g., metal liner 802) includes a first dimension (e.g., x-axis), a second dimension (z-axis), and a third dimension in which the third dimension (e.g., length along the y-axis) is elongated compared to the first and second dimensions (e.g., x and z axes), the first, the second, and the third dimensions being substantially orthogonal; the third dimension is elongated in a direction (e.g., y-axis) separating the channel region (e.g., fin 202) and a contact. The third dimension is elongated in a direction (e.g., y-axis) ranging from a first interface toward an area beneath a second interface, the first interface being between a contact and the first epitaxial region (e.g., between the bottom source/drain contact 1314 and the bottom source/drain regions 402 and 602), the second interface being between the first epitaxial region and the channel region (e.g., between the bottom source/drain regions 402 and 602 and the fin 202). The conductive piece (e.g., metal liner 802) is a metallic liner configured to assist with carrying electrical current between the channel region and a contact. The conductive piece includes a metal and other materials, the other materials including silicon, silicon germanium, or nitrides.

FIG. 15 depicts a flowchart of a method 1500 of forming a buried metal liner inside source/drain epitaxial material for vertical transport field effect transistors according to one or more embodiments. Reference can be made to any figures discussed herein. At block 1502, the method 1500 includes providing a transistor (e.g., PFET and/or NFET) including a channel region (e.g., fins 202) separating a first epitaxial region (e.g., bottom source/drain regions 402 and 602) from a second epitaxial region (e.g., top source/drain regions 1306 and 1308). At block 1504, the method 1500 includes embedding a conductive piece (e.g., metal liner 802) in the first epitaxial region, wherein a contact (e.g., bottom source/drain contact 1314) is coupled to the first epitaxial region, the conductive piece being electrically coupled to both the channel region and the contact.

Gate material formed around the fins includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

In one or more embodiments, the ILD material can be SiO₂, SiN, a low-k dielectric material or an ultra-low-k dielectric material. Low-k dielectric materials may generally include dielectric materials having a k value of about 3.9 or less. The ultralow-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present disclosure for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the disclosure may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
a transistor comprising a channel region separating a first epitaxial region from a second epitaxial region; and
a conductive piece embedded in the first epitaxial region.

2. The semiconductor structure of claim 1, wherein the conductive piece comprises a metal.

3. The semiconductor structure of claim 1, wherein the conductive piece is metallic.

4. The semiconductor structure of claim 1, wherein the conductive piece extends from the channel region to a contact.

5. The semiconductor structure of claim 1, wherein:
the conductive piece comprises a first dimension, a second dimension, and a third dimension in which the third dimension is elongated compared to the first and the second dimensions, the first, the second, and the third dimensions being substantially orthogonal; and
the third dimension is elongated in a direction ranging from a first interface toward an area beneath a second interface, the first interface being between a contact and the first epitaxial region, the second interface being between the first epitaxial region and the channel region.

6. The semiconductor structure of claim 1, wherein the conductive piece is a metallic liner configured to assist with carrying electrical current between the channel region and a contact.

7. The semiconductor structure of claim 1, wherein the conductive piece comprises a metal and other materials, the other materials comprising silicon, silicon germanium, or nitride.

8. A method comprising:
providing a transistor comprising a channel region separating a first epitaxial region from a second epitaxial region; and
embedding a conductive piece in the first epitaxial region.

9. The method of claim 8, wherein the conductive piece comprises a metal.

10. The method of claim 8, wherein the conductive piece is metallic.

11. The method of claim 8, wherein the conductive piece extends from the channel region to a contact.

12. The method of claim 8, wherein:
the conductive piece comprises a first dimension, a second dimension, and a third dimension in which the third dimension is elongated compared to the first and the second dimensions, the first, the second, and the third dimensions being substantially orthogonal; and
the third dimension is elongated in a direction ranging from a first interface toward an area beneath a second interface, the first interface being between a contact and the first epitaxial region, the second interface being between the first epitaxial region and the channel region.

13. The method of claim 8, wherein the conductive piece is a metallic liner configured to assist with carrying electrical current between the channel region and a contact.

14. The method of claim 8, wherein the conductive piece comprises a metal and other materials, the other materials comprising silicon, silicon germanium, or nitride.

15. A method comprising:
providing a transistor comprising a channel region separating a first epitaxial region from a second epitaxial region; and
embedding a conductive piece in the first epitaxial region, wherein a contact is coupled to the first epitaxial region, the conductive piece being electrically coupled to both the channel region and the contact.

16. The method of claim 15, wherein the conductive piece comprises a metal.

17. The method of claim 15, wherein the conductive piece is metallic.

18. The method of claim 15, wherein the conductive piece extends from the channel region to the contact.

19. The method of claim 15, wherein:
the conductive piece comprises a first dimension, a second dimension, and a third dimension in which the third dimension is elongated compared to the first and the second dimensions, the first, the second, and the third dimensions being substantially orthogonal; and
the third dimension is elongated in a direction ranging from a first interface toward an area beneath a second interface, the first interface being between the contact and the first epitaxial region, the second interface being between the first epitaxial region and the channel region.

20. The method of claim 15, wherein the conductive piece is a metallic liner configured to assist with carrying electrical current between the channel region and the contact.
